(19) United States
(12) Patent Application Publication
(10) Pub. No.: US 2001/0000157 A1
(43) Pub. Date: Apr. 5, 2001

(54) Semiconductor device and method of making the same

(75) Inventors: Hiroshi Oka, Ukyo-ku (JP); Masaaki Hiromitsu, Ukyo-ku (JP)

Correspondence Address: Attention: Curtis B. Hamre, MERCHANT & GOULD P.C., P.O. Box 2903, Minneapolis, MN, 55402-0903, US

(73) Assignee: ROHM CO., LTD., UKYO-KU, KYOTO (JP)

(21) Appl. No.: 09/729,558

(22) Filed: Dec. 4, 2000

Related U.S. Application Data
(62) Division of application No. 09/172,548, filed on Oct. 14, 1998.

(30) Foreign Application Priority Data
Oct. 16, 1997 (JP) 9-283611
Oct. 16, 1997 (JP) 9-283612
Oct. 21, 1997 (JP) 9-288280

(51) Int. Cl. H01L 41/09; H01L 21/60; H01L 23/49

(52) U.S. Cl. 438/617; 257/693

(57) ABSTRACT

A semiconductor device is provided which includes an upper semiconductor chip and a lower semiconductor chip attached to the upper semiconductor chip. The upper semiconductor chip is formed with a first connection pad, while the lower semiconductor chip is formed with a second connection pad. The semiconductor device also includes a deformable stud bump made of gold and arranged between the first and the second connection pads. The deformable stud bump includes an upwardly pointed portion before it is pressed and deformed by the first connection pad of the upper semiconductor chip. The pointed portion serves to break through an oxide film formed on the first connection pad of the upper semiconductor chip. The semiconductor device further includes an adhesive resin layer applied between the upper and lower semiconductor chips.

### BACKGROUND OF THE INVENTION

1. 1. Field of the Invention

2. The present invention relates to a semiconductor device including two semiconductor chips electrically connected to each other. The present invention also relates to a method of making such a semiconductor device.

3. 2. Description of the Related Art

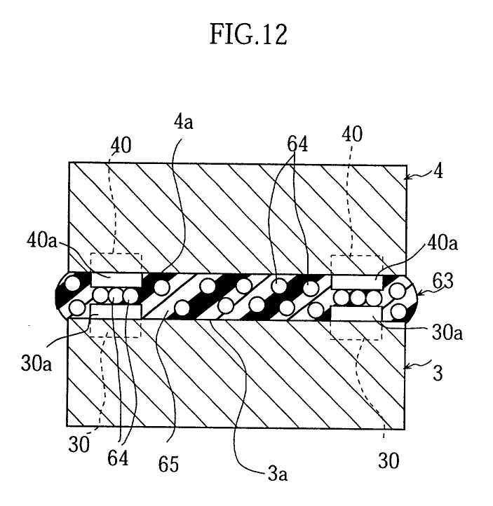

4. Referring to FIG. 12 of the accompanying drawings, a conventional semiconductor device including two semiconductor chips is shown. In the illustrated arrangement, an upper semiconductor chip 4 is fixed to a lower semiconductor chip 3 by an adhesive resin layer 63. The resin layer 63 is made of an adhesive resin material 65 in which electrically conductive particles 64 are distributed. Such an conductive resin material is known as “anisotropic conductive resin.” The resin material 65 is a thermosetting resin which will harden at a temperature of 200° C. for example.

5. The lower semiconductor chip 3 has a principal surface 3a in which a suitable number of connection pads 30 are embedded. Each connection pad 30 supports a conductive bump 30a. Though not illustrated, a suitable wiring pattern is formed on the principal surface 3a to be electrically connected to the pads 30. Similarly, the upper semiconductor chip 4 has a principal surface 4a provided with connection pads 40 embedded therein. The connection pads 40 may correspond in number and position to the connection pads 30 of the lower semiconductor chip 3. Each connection pad 40 carries a conductive bump 40a. A wiring pattern (not shown) is formed on the principal surface 4a to be electrically connected to the pads 40.

6. As seen from FIG. 12, the lower bumps 30a are electrically connected to the upper bumps 40a by some of the conductive particles 64. The remaining conductive particles 64 (i.e., the ones which are not located between the bumps 30a and the bumps 40b) are spaced from each other, so that they are electrically insulated.

7. The above conventional semiconductor device has been found disadvantageous in the following points.

8. First, the conductive particles 64 may fail to be uniformly distributed within the resin layer 63 and may unduly be concentrated at particular points. In such a case, the electrical connection between the upper bumps 40a and the lower bumps 30a may not be properly established due to shortage or even complete lack of conductive particles 64 between the upper and lower bumps 40a, 30a. In this sense, an anisotropic conductive resin material cannot reliably be used for electrically connecting the two semiconductor chips 3, 4.

9. Secondly, in some applications, the lower semiconductor chip 3 (and/or the upper semiconductor chip 4) may be a ferroelectric random access memory (FRAM) chip which utilizes spontaneous polarization of ferroelectrics. The FRAM is a memory in which information can be rewritten at high speed and at low voltage by inverting the polarization of the ferroelectrics. Unfavorably, those ferroelectrics, when heated to high temperatures, may lose ferroelectricity, thereby failing to undergo spontaneous polarization. Such an adverse effect may remain after the ferroelectrics are cooled to the previous temperature. Thus, when the thermosetting resin layer 63 is heated up to about 200° C. for fixing the lower semiconductor chip 3 (or FRAM chip in the present case) to the upper chip 4, the FRAM chip 3 in the semiconductor device finally produced may fail to function properly or even may not work at all.

10. Thirdly, according to the conventional arrangement, the adhesive resin layer 63 needs to be prepared separately for each of plural semiconductor devices which may differ in size. For such separate preparation, additional steps may be needed for adjusting the amount of the thermosetting resin material for the principal surface of each semiconductor chip (lower or upper), and thereafter for applying it onto the principal surface. Such additional steps will unfavorably increase the production costs, while lowering the production efficiency.

11. Finally, in using an anisotropic conductive resin for electrically connecting the lower and the upper chips 3 and 4, the forming of the conductive bumps 30a, 40a (or similar protrusions) is inevitable. Without these bumps, the principal surface 3a may entirely be connected to the principal surface 4a, which is unfavorable since the wiring patterns formed on the respective principal surfaces will be shortened. Clearly, the forming of the conductive bumps 30a, 40a will increase the production costs.

### SUMMARY OF THE INVENTION

12. It is, therefore, an object of the present invention to provide a semiconductor device capable of overcoming the problems described above.

13. Another object of the present invention is to provide a method of making such a semiconductor device.

14. According to a first aspect of the present invention, there is provided a semiconductor device comprising:

15. a semiconductor chip formed with a first connection pad;

16. a counterpart element attached to the semiconductor chip, said element being formed with a second connection pad; and

17. a deformable stud bump arranged between the first and the second connection pads for electrical connection thereof.

18. With such an arrangement, since the deformable stud bump is provided between the first and the second connection pads, the two connection pads are reliably connected to each other.

19. The counterpart element may be a substrate supporting the semiconductor chip or be another semiconductor chip.

20. The semiconductor device may further comprise an adhesive resin layer arranged between the semiconductor chip and the counterpart element. The adhesive resin layer may be made of a thermosetting resin such as an epoxy resin and a phenol resin.

21. Preferably, the semiconductor chip may include a first principal surface in which the first connection pad is made, while the counterpart element may include a second principal surface in which the second connection pad is made, wherein the first and second principal surfaces are enclosed by the adhesive resin layer.

22. The stud bump may be made of a precious metal such as gold.

23. According to a preferred embodiment, the semiconductor chip may be provided with a first connection bump formed on the first connection pad, while the counterpart element may be provided with a second connection bump formed on the second connection pad. In such an instance, the stud bump is arranged between the first and the second connection bumps.

24. Preferably, the first and the second connection bumps may be made of a precious metal such as gold.

25. According to a preferred embodiment, the counterpart element may be another semiconductor chip.

26. The semiconductor device may further comprise a base substrate for supporting the two semiconductor chips. In such an instance, the base substrate may be formed with a connection terminal, wherein said another semiconductor chip may be formed with a third connection pad which is electrically connected to the connection terminal of the base substrate.

27. In some applications, at least one of the two semiconductor chips may be a ferroelectric random access memory chip.

28. According to a second aspect of the present invention, there is provided a method of making a semiconductor device including a semiconductor chip and a counterpart element attached to the semiconductor chip, the semiconductor chip being provided with a first connection pad formed in a first principal surface of the chip, the counterpart element being provided with a second connection pad formed in a second principal surface of the element, the method comprising the steps of:

29. forming a deformable stud bump on the second connection pad of the counterpart element;

30. applying an adhesive resin in a liquid state to the second principal surface of the counterpart element;

31. pressing the first connection pad against the stud bump formed on the second connection pad; and

32. fixing the semiconductor chip to the counterpart element by hardening the adhesive resin.

33. Preferably, the deformable stud bump may be made of gold and include a pointed portion against which the first connection pad is pressed.

34. With such an arrangement, even when an oxide film is formed over the first connection pad, the pointed portion of the stud bump advantageously breaks through the oxide film, whereby the stud bump is reliably connected to the first connection pad.

35. In a preferred embodiment, the adhesive resin may be applied to the second principal surface in a manner such that the applied adhesive resin is spaced from the second connection pad.

36. With such an arrangement, the stud bump formed on the second connection pad is prevented from being covered by the applied adhesive resin, which facilitates electrical connection of the stud bump to the first connection pad.

37. However, according to the present invention, it is also possible to apply the adhesive resin to the second principal surface in a manner such that the applied adhesive resin encloses the second connection pad and the stud bump. Even in such an instance, the pointed portion of the stud bump will reliably be brought into contact with the first connection pad without being interfered with the applied resin.

38. According to a third aspect of the present invention, there is provided a method of making a semiconductor device including a semiconductor chip, a counterpart element attached to the semiconductor chip and a base substrate supporting the semiconductor chip and the counterpart element, the semiconductor chip being provided with a first connection pad formed in a first principal surface of the chip, the counterpart element being provided with a second connection pad and a third connection pad formed in a second principal surface of the element, the base substrate being provided with a connection terminal, the method comprising the steps of:

39. connecting the third connection pad to the connection terminal of the base substrate by a metal wire;

40. forming a deformable stud bump on the second connection pad;

41. applying an adhesive resin to the second principal surface of the counterpart element; and

42. pressing the first connection pad against the stud bump formed on the second connection pad.

43. Other features and advantages of the present invention should become clear from the detailed description to be made hereinafter referring to the accompanied drawings.

### BRIEF DESCRIPTION OF THE DRAWINGS

44. In the accompanying drawings:

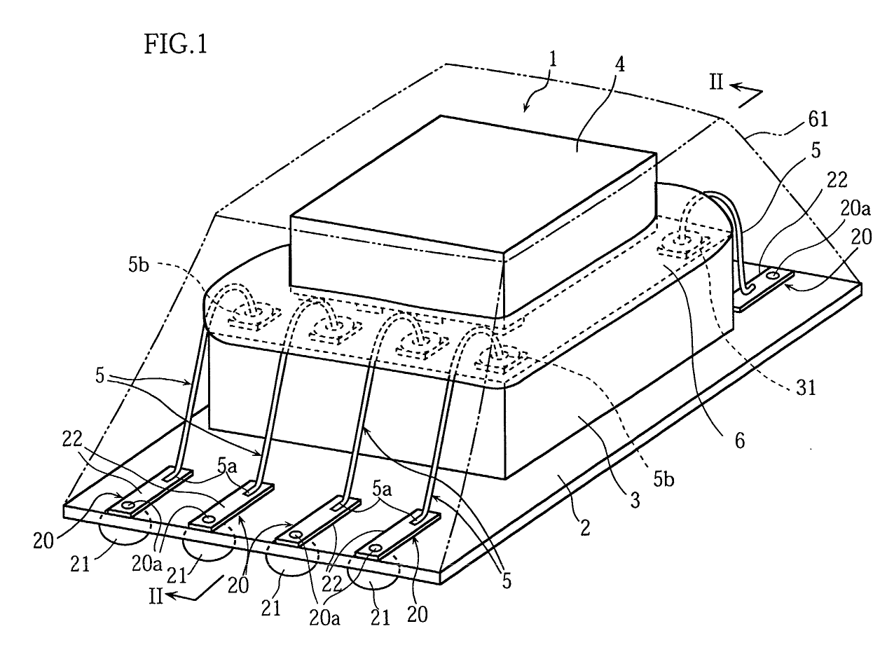

45. FIG. 1 is a perspective view showing a semiconductor device according to a first embodiment of the present invention;

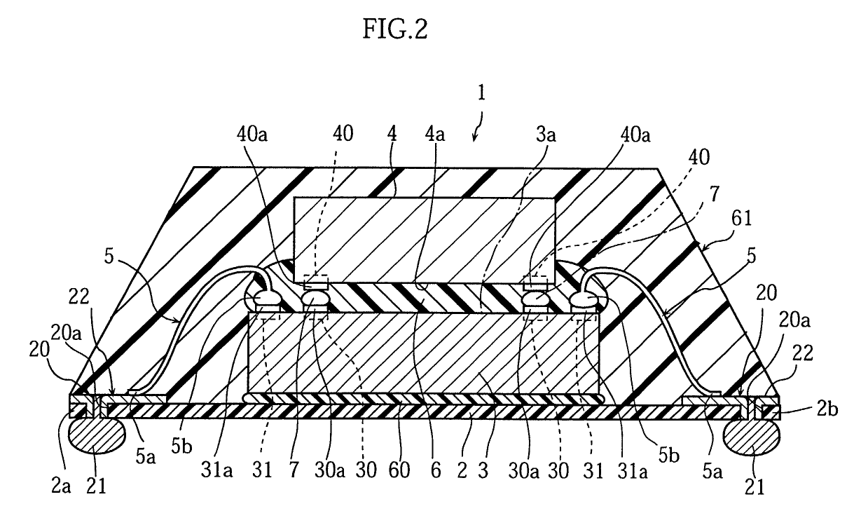

46. FIG. 2 is a sectional view taken along lines II—II in FIG. 1;

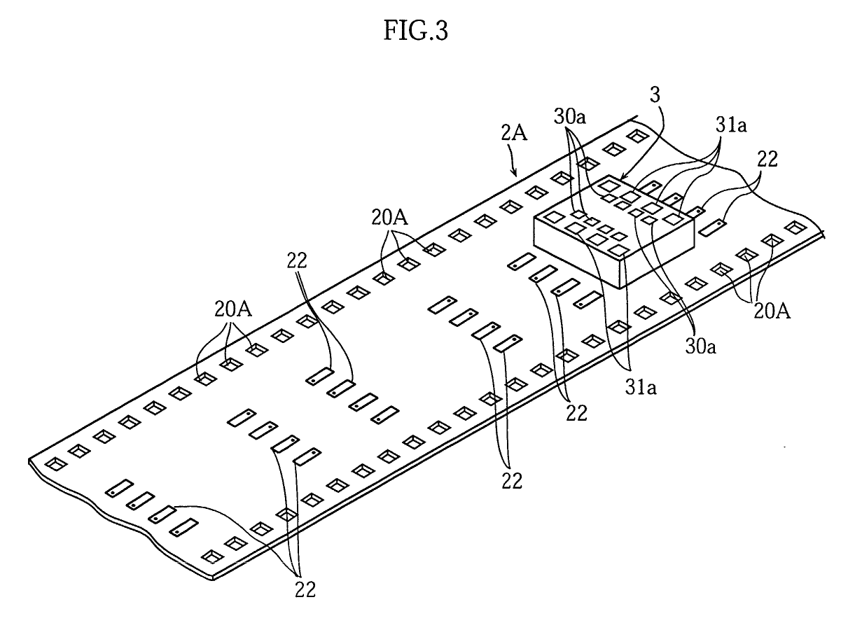

47. FIG. 3 is a perspective view showing a film substrate together with a lower semiconductor chip of the semiconductor device of FIG. 1;

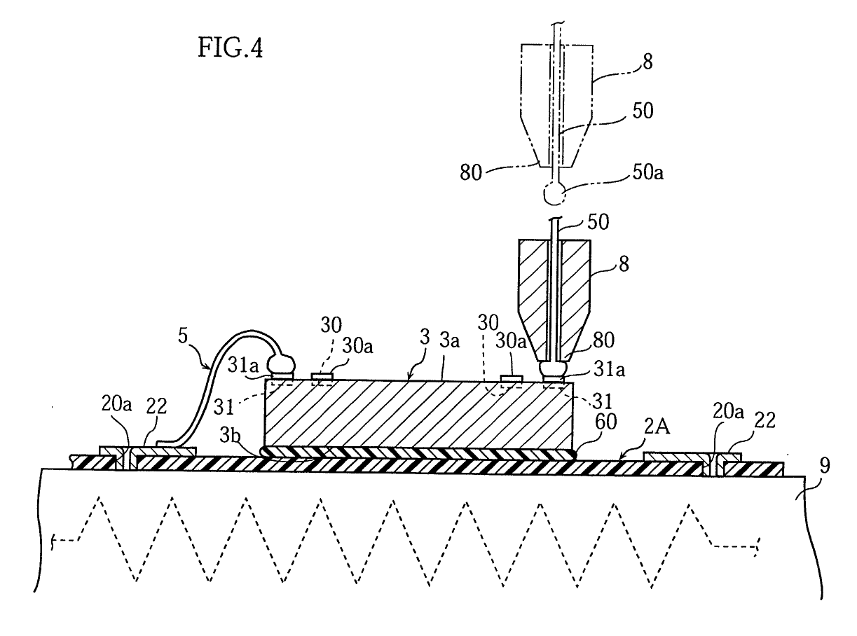

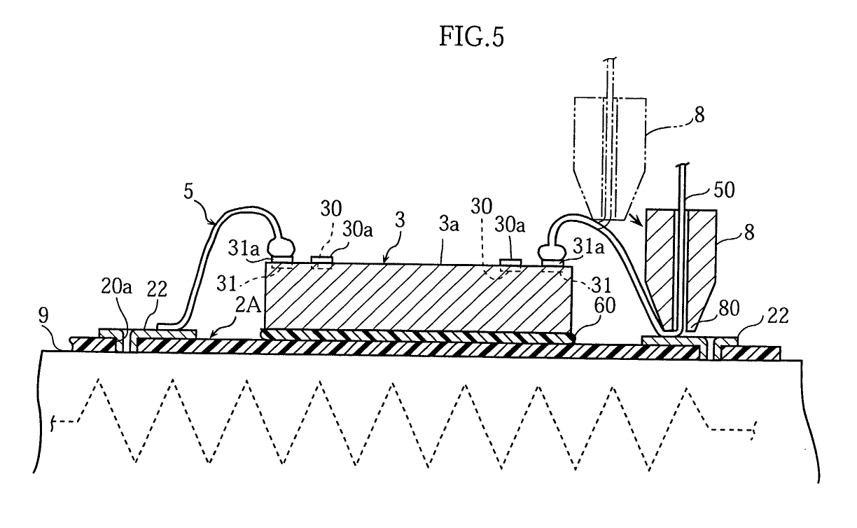

48. FIGS. 4 and 5 illustrate how wire-bonding is performed for connecting connection pads of the lower semiconductor chip to terminals formed on the film substrate;

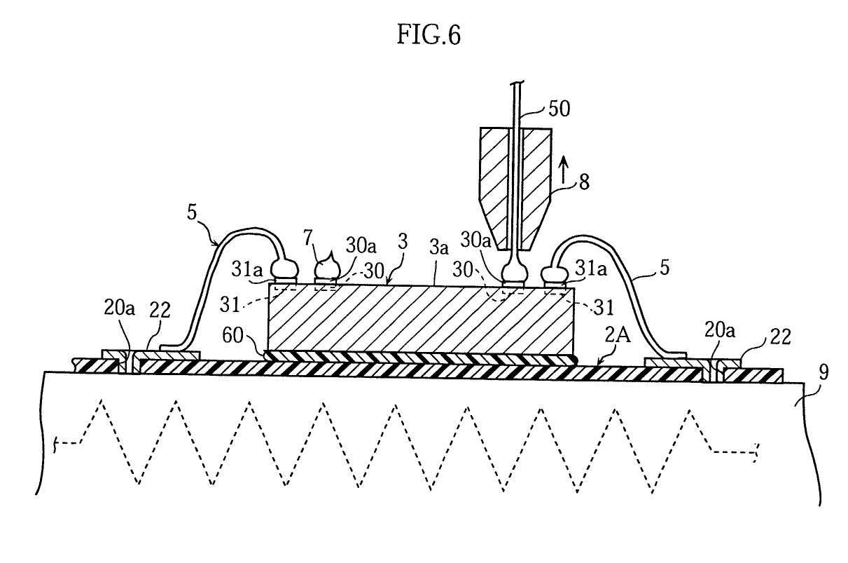

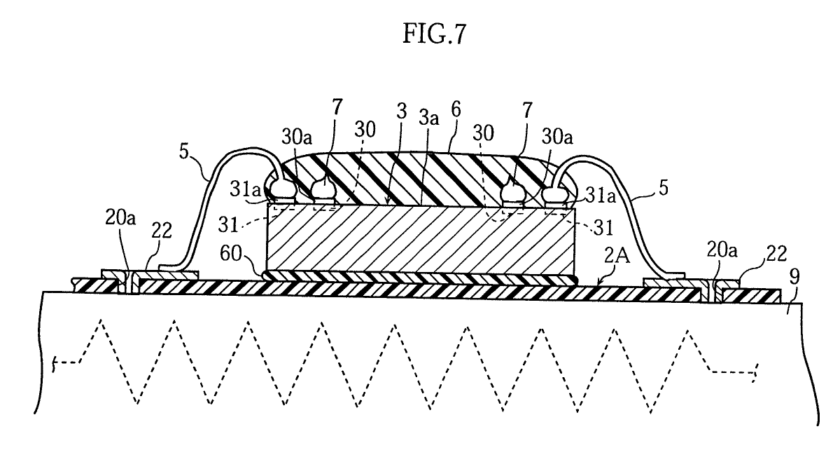

49. FIGS. 6 and 7 illustrate how stud bumps are made using a conventional capillary tool;

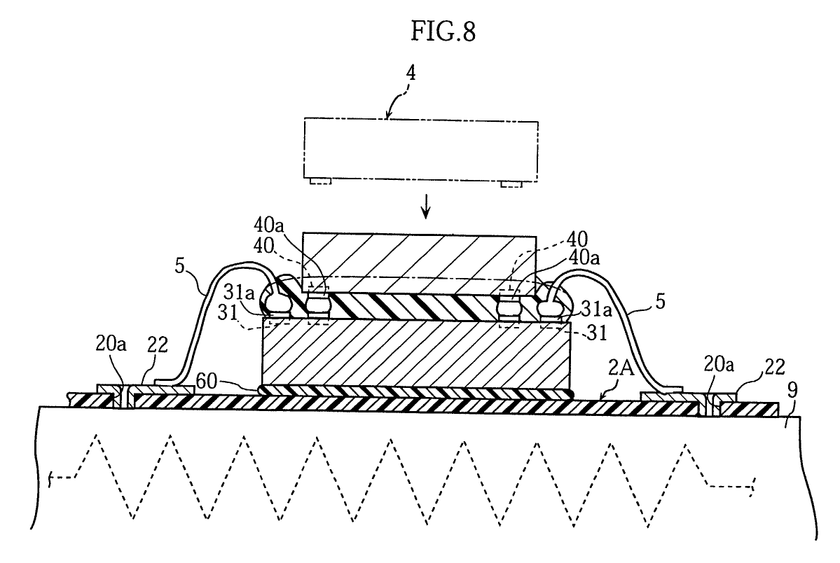

50. FIG. 8 illustrates how an upper semiconductor chip is mounted onto the lower semiconductor chip;

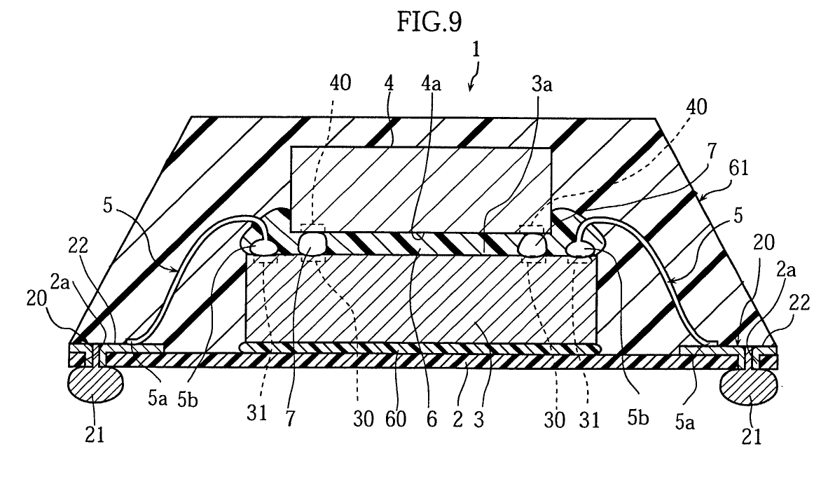

51. FIG. 9 shows a semiconductor device according to a second embodiment of the present invention;

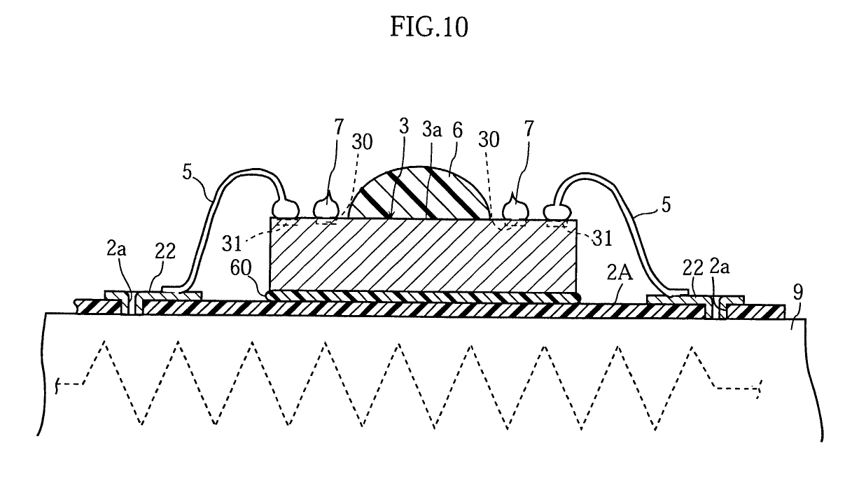

52. FIG. 10 illustrates a step for applying an adhesive resin onto the lower semiconductor chip;

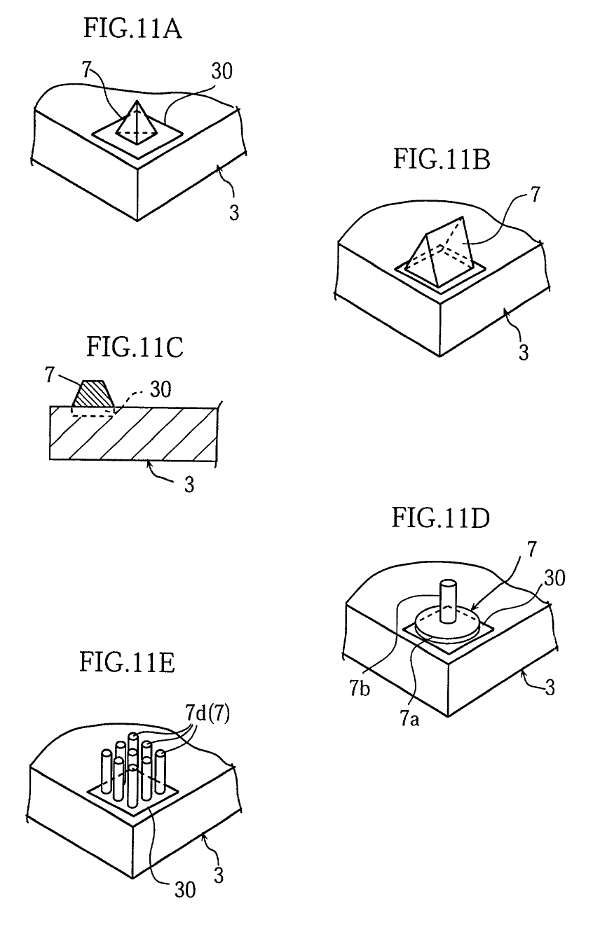

53. FIGS. 11A-11E show examples of modified stud bumps; and

54. FIG. 12 is a sectional view showing a conventional semiconductor device including two semiconductor chips.

### DETAILED DESCRIPTION OF THE PREFERRED EMBODIMENT

55. The preferred embodiments of the present invention will be specifically described below with reference to the accompanying drawings.

56. Reference is first made to FIG. 1 which is a perspective view showing a semiconductor device according to a first embodiment of the present invention. The illustrated semiconductor device 1 includes a rectangular film substrate 2 made of a polyimide resin for example, a first or lower semiconductor chip 3 directly supported by the film substrate 2, and a second or upper semiconductor chip 4 mounted on the first semiconductor chip 3. In an application, at least one of the semiconductor chips may be a ferroelectric random access memory (FRAM) chip. The first and the second semiconductor chips 3, 4 are electrically connected to each other in a manner described hereinafter.

57. Referring also to FIG. 2, which is a sectional view taken along lines II—II in FIG. 1, the film substrate 2 is formed with eight (8) through-holes 20a which are divided equally into two groups. Four through-holes in the first group are arranged along a first end 2a of the substrate 2, while the remaining four through-holes in the second group are arranged along a second end 2b opposite to the first end 2a. At the locations of the respective through-holes 20a, terminals 20 are provided. Each of the terminals 20 includes a strip portion 22 formed on the upper surface of the film substrate 2 and a ball portion 21 formed on the bottom surface of the same substrate. The strip portion 22 and the ball portion 21 are electrically connected to each other via one of the through-holes 20a. The strip portion 22 may be made of copper for example, whereas the ball portion 21 may be made of solder for example.

58. As best shown in FIG. 2, the first chip 3 has a principal surface (upper surface) 3a, while the second chip 4 has a principal surface (bottom surface) 4a held in facing relation to the principal surface 3a of the first chip 3. The principal surface 3a of the first chip 3 is provided with a plurality of first electrode pads 30 and a plurality of second electrode pads 31. The principal surface 4a of the second chip 4 is provided with a plurality of third electrode pads 40. Though not shown, electronic elements as required are mounted on the principal surface 3a. A wiring pattern (not shown) is formed on the surface 3a for connecting the electronic elements to the first and/or the second electrode pads 30, 31. Similarly, electronic elements (not shown) are mounted on the principal surface 4a. A wiring pattern (not shown) is formed on the principal surface 4a for connecting the electronic elements to the third electrode pads 40. On each of the first electrode pads 30, a first connection bump 30a is mounted which is electrically connected to the first electrode pad 30. Similarly, a second connection bump 31a is mounted on each of the second electrode pads 31, while a third connection bump 40a is mounted on each of the third electrode pads 40. Those connection bumps 30a, 31a, 40a may be made of aluminum for example. However, preferably, those bumps are made of a precious metal such as gold. As is well known, gold is less likely to be oxidized than other non-precious metals such as aluminum. Thus, the connection bumps 30a, 31a, 40a made of gold are less prone to be covered with oxide film. Therefore, in forming a stud bump 7 on each of the first connection bumps 30a in a manner described below, there is no need to perform an additional step for removing an oxide film from the surface of the connection bump 30a. Further, when the stud bump 7 is also made of gold, the stud bump can be easily attached to the first connection bump 30 (due to connection between members of the same metal).

59. The second connection bumps 31a are electrically connected to the terminals 20 by bonding wires 5 made of gold. Each bonding wire 5 has an outer end 5a connected to the terminal 20 and an inner end 5b connected to the second connection bump 31a. The connection of the outer and inner ends 5a, 5b of each bonding wire 5 may be performed using a thermal ultrasonic bonding method, as will be described later.

60. The first and second semiconductor chips 3, 4 and the bonding wires 5 are enclosed by a package 61 which may be made of a resin material such as epoxy.

61. As shown in FIG. 2, the first and the second semiconductor chips 3, 4 are electrically connected to each other via a plurality of stud bumps 7 provided between the first connection bumps 30a and the third connection bumps 40a. Those stud bumps are preferably made of gold. For mechanical connection of the first and second semiconductor chips 3, 4, use is made of an adhesive resin 6 applied between the principal surfaces 3a, 4a of the respective chips. The adhesive resin may be a thermosetting resin such as epoxy resin, phenol resin or the like.

62. Each of the stud bumps 7 illustrated in FIG. 2 is squeezed between the connection bumps 30a and 40a so that it is deformed from its original shape. As shown in FIG. 6, the stud bump 7 initially has an upwardly pointed portion 7a.

63. Referring to FIGS. 2 and 6, the third connection bump 40a of the upper semiconductor chip 4 is pressed down against the upwardly pointed portion 7a of the stud bump 7. In this manner, even when an oxide film is formed on the surface of the third connection bump 40a, the stud bump 7 is reliably connected to the third connection bump because the pointed portion 7a of the stud bump can break through the oxide film so that the surface of the third connection bump 40a is exposed.

64. Further, according to the illustrated embodiment, excellent electrical connection between the first and the second semiconductor chips 3, 4 is maintained since the two semiconductor chips 3, 4 are firmly attached to each other by the hardened resin layer 6. In this regard, it should be appreciated that the resin material of the layer 6 contracts as it transforms from a fluid state into a solid state. As a result, after the resin layer 6 is hardened, the first and second semiconductor chips 3, 4 are advantageously urged toward each other. In this condition, the first connection bump 30a and the third connection bump 40a are suitably pressed onto the stud bump 7 from the opposite directions. Thus, as stated above, the first and second semiconductor chips 3, 4 are electrically connected to each other in a reliable manner.

65. Still further, the non-illustrated electronic elements and wiring patterns formed on the principal surfaces 3a and 4a are enclosed by the resin layer 6. In this condition, the electronic elements and wiring patterns are advantageously protected from damage.

66. Reference is now made to FIGS. 3-8 illustrating how the above semiconductor device 1 is produced.

67. First, as shown in FIG. 3, an elongated resin film 2A is prepared. The resin film 2A, which may be made of a polyimide resin for example, is formed with a plurality of feed holes 20A arranged along its longitudinal edges. Though not shown, use is made of a traction mechanism coming into engagement with those feed holes 20A for advancing the resin film 2A along a predetermined production line.

68. Then, strip portions 22 of the terminals 20 are formed on the upper surface of the resin film 2A. The strip portions 22 may be made in the following manner. First, a layer of copper is formed on the upper surface of the resin film 2A by sputtering, vacuum evaporation, or chemical vapor deposition (CVD) for example. Then, the copper layer is etched to form the individual strip portions 22.

69. Then, the first semiconductor chips 3 (only one is shown) are mounted onto the resin film 2A. Each of the first semiconductor chip 3 is formed with first and second connection pads 30, 31 together with first and second connection bumps 30a, 31a. For fixing the first chips 3 to the resin film 2A, use is made of an adhesive resin 60 (see FIG. 2). The adhesive resin 60 may be made of a resin which will harden at room temperature. Alternatively, use may be made of other resins such as epoxy resin and phenol resin which will harden at much higher temperatures.

70. Then, as shown in FIGS. 4 and 5, the strip portions 22 are electrically connected to the second connection bumps 31a by the bonding wires 5. Such connection is performed by thermal ultrasonic bonding. Specifically, the resin film 2A is placed upon a support base 9. As can be seen from FIG. 1, the support base 9 incorporates heating means (the zigzag broken lines). Thus, upon turning on the heating means, the resin film 2A and the first semiconductor chip 3 are heated to a temperature between 100° C. and 200° C. In this heated condition, a first bonding step shown in FIG. 4 and a second bonding step shown in FIG. 5 are performed.

71. In the first bonding step (and the second bonding step as well), use is made of a capillary 8. As shown in FIG. 4, gold wire 50 extends through the capillary 8, with its tip or lower end caused to protrude from a lower portion 80 of the capillary. The lower end of the gold wire 50 is heated in e.g. hydrogen flame (not shown) to be melted into a ball portion 50a. Then, the capillary 8 is lowered toward the first semiconductor chip 3 so that the ball portion 50a is pressed onto the second connection bump 31a. At this time, ultrasonic vibrations are applied to the ball portion 50a so that the ball portion is properly fixed to the connection bump 31a.

72. Then, in the second bonding step shown in FIG. 5, the capillary 8 is moved to the strip portion 22 while the gold wire 50 is suitably paid out from the capillary. Then, the gold wire 50 is pressed onto the strip portion 22 by the lower portion 80 of the capillary 8. At this time again, ultrasonic vibrations are applied to the pressed portion of the gold wire 50. After the gold wire 50 is fixed to the strip portion 22, the capillary 8 may be slightly moved horizontally away from the fixed portion of the gold wire 50. Then, the capillary 8 is lowered onto the strip portion 22 for cutting off the gold wire at the fixed portion.

73. After a predetermined number of bonding wires 5 are connected to the connection bumps 31a and the strip portions 22, a stud bump 7 is formed on each of the first connection bumps 30a. The forming of the stud bump 7 may be performed in a manner similar to the first bonding step. Specifically, with the resin film 2A placed on the support base 9, a ball portion 50a of the gold wire 50 is pressed onto the first connection bump 30a to be properly fixed to the connection bump 30a. Thereafter, the capillary 8 is moved upward. At this time, the gold wire 50 is not paid out from the capillary 8. As a result, the gold wire 50 is ripped off, leaving an upwardly pointed portion 7a.

74. As stated above, the forming of the stud bumps 7 can be performed by using the capillary 8 which is also used for bonding the wires 5. Thus, according to the present invention, there is no need to prepare an additional apparatus for making the stud bumps 7.

75. Then, as shown in FIG. 7, an adhesive resin 6 in a fluid state is applied over the principal surface 3a of the first semiconductor chip 3 in a manner such that the inner ends of the bonding wires 5 and the stud bumps 7 are completely enclosed. Preferably, the adhesive resin 6 may be epoxy resin or phenol resin which will solidify at about 100° C.

76. Then, as shown in FIG. 8, the second semiconductor chip 4 is mounted onto the first semiconductor chip 3 so that the third connection bumps 40a come into contact with the stud bumps 7. Though not illustrated, the mounting of the second chip 4 may be performed by using a conventional chip mounting device. After properly mounted on the first chip 3, the second semiconductor chip 4 is pressed down toward the first semiconductor chip. In this process, the pointed portions 7a of the respective stud bumps 7 are crushed by the third connection bumps 40a. At this time, the pointed portions 7a of the respective stud bumps 7 can break through possible oxide films formed on the surfaces of the third connection bumps 40a. As a result, the stud bumps 7 will come into direct contact with the third connection bumps 40a, thereby providing excellent electrical conduction. In this way, by way of the deformable stud bumps 7, the first connection bumps 30a are reliably connected to the third connection bumps 40a.

77. As is easily understood, when the second chip 4 is pressed toward the first chip 3 in the manner described above, the lower ball-like portions of the respective stud bumps 7 are also deformed (crushed) to some extent under the pressure of the third connection bumps 40a. As a result, the contact area of the stud bumps 7 with respect to the third connection bumps 40a is advantageously increased, which ensures good electrical conduction between the two bumps 7, 40a.

78. In addition, since the respective stud bumps 7 can be deformed when the second chip 4 is mounted onto the first chip 3, the positional adjustment of the second chip 4 with respect to the first chip 3 can be easily performed. For instance, it is possible to position the second chip 4 in parallel to the first chip 3.

79. Then, a protection package 61 is formed to enclose the first and second semiconductor chips 3, 4, and the bonding wires 50. The package 61 may be made of an epoxy resin for example. Thereafter, solder ball portions 21 (FIG. 2) are made on the bottom surface of the resin film 2A. As previously described, the resulting ball portions 21 are held in electrical conduction with the strip portions 22 via the through-holes 20a formed in the film substrate 2A.

80. Finally, the elongated resin film 2A is cut to provide a plurality of individual semiconductor devices 1.

81. Reference is now made to FIG. 9 which is a sectional view showing a semiconductor device 1 according to a second embodiment of the present invention. As can be seen, the semiconductor device 1 of the second embodiment is the same as the semiconductor device of the first embodiment except for some differences described below.

82. Specifically, according to the second embodiment, a stud bump 7 is held in direct contact with a first connection pad 30 of a first semiconductor chip 3 and a third connection pad 40 of a second semiconductor chip 4. Further, an inner end 5b of a bonding wire 5 is held in direct contact with a second connection pad 31 of the first semiconductor chip 3. In such an arrangement, since there is no need to form connection bumps 30a, 31a, 40a present in the first embodiment, production costs are reduced and the production efficiency is improved.

83. Steps for making the semiconductor device of the second embodiment are substantially similar to those for making the semiconductor device of the first embodiment, except that steps for making the omitted elements (i.e., the connection bumps 30a, 31a, 40a) do not need to be performed in the second embodiment. Alternations may be possible. For instance, as shown in FIG. 10, an adhesive resin 6 in a liquid state may be applied only to a central region (between the stud bumps 7) of the principal surface 3a of the first semiconductor chip 3, so that the applied resin 6 is spaced from the first connection pads 30. Even in this arrangement, the adhesive resin 6 will be properly spread over the entire principal surface 3a due to its fluidity when a second semiconductor chip (not shown) is mounted onto the first semiconductor chip 3 from above.

84. The preferred embodiments of the present invention being thus described, it is obvious that the same may be varied in various ways. For instance, as shown in FIGS. 11A-11E, a stud bump 7 may be made into various forms. Specifically, the stud bump 7 may be formed into a triangular pyramid (FIG. 11A), a prism-like configuration (FIG. 11B), or a truncated prism (FIG. 11C). Further, as shown in FIG. 11D, the stud bump 7 may include a circular base 7a and an upright column 7b extending from the circular base. Still further, the stud bump 7 may include a plurality of upright columns 7d. Such variations should not be regarded as a departure from the spirit and scope of the invention, and all such variations as would be obvious to those skilled in the art are intended to be included within the scope of the appended claims.

CLAIMS

1. A semiconductor device comprising:
a semiconductor chip formed with a first connection pad;
a counterpart element attached to the semiconductor chip, said element being formed with a second connection pad; and
a deformable stud bump arranged between the first and the second connection pads for electrical connection thereof.

2. The semiconductor device according to claim 1, further comprising an adhesive resin layer arranged between the semiconductor chip and the counterpart element.

3. The semiconductor device according to claim 2, wherein the adhesive resin layer is made of an epoxy resin.

4. The semiconductor device according to claim 2, wherein the adhesive resin layer is made of a phenol resin.

5. The semiconductor device according to claim 2, wherein the semiconductor chip includes a first principal surface in which the first connection pad is made, the counterpart element including a second principal surface in which the second connection pad is made, the first and second principal surfaces being enclosed by the adhesive resin layer.

6. The semiconductor device according to claim 1, wherein the stud bump is made of a precious metal.

7. The semiconductor device according to claim 6, wherein the precious metal is gold.

8. The semiconductor device according to claim 1, wherein the semiconductor chip is provided with a first connection bump formed on the first connection pad, the counterpart element being provided with a second connection bump formed on the second connection pad, the stud bump being arranged between the first and the second connection bumps.

9. The semiconductor device according to claim 8, wherein the first and the second connection bumps are made of a precious metal.

10. The semiconductor device according to claim 9, wherein the precious metal is gold.

11. The semiconductor device according to claim 1, wherein the counterpart element is another semiconductor chip.

12. The semiconductor device according to claim 11, further comprising a base substrate for supporting the two semiconductor chips, the base substrate being formed with a connection terminal, wherein said another semiconductor chip is formed with a third connection pad which is electrically connected to the connection terminal of the base substrate.

13. The semiconductor device according to claim 11, wherein at least one of the two semiconductor chips is a ferroelectric random access memory chip.

14. A method of making a semiconductor device including a semiconductor chip and a counterpart element attached to the semiconductor chip, the semiconductor chip being provided with a first connection pad formed in a first principal surface of the chip, the counterpart element being provided with a second connection pad formed in a second principal surface of the element, the method comprising the steps of:
forming a deformable stud bump on the second connection pad of the counterpart element;
applying an adhesive resin in a liquid state to the second principal surface of the counterpart element;
pressing the first connection pad against the stud bump formed on the second connection pad; and
fixing the semiconductor chip to the counterpart element by hardening the adhesive resin.

15. The method according to claim 14, wherein the deformable stud bump is made of gold and includes a pointed portion against which the first connection pad is pressed.

16. The method according to claim 14, wherein the adhesive resin is applied to the second principal surface in a manner such that the applied adhesive resin is spaced from the second connection pad.

17. The method according to claim 14, wherein the adhesive resin is applied to the second principal surface in a manner such that the applied adhesive resin encloses the second connection pad and the stud bump.

18. A method of making a semiconductor device including a semiconductor chip, a counterpart element attached to the semiconductor chip and a base substrate supporting the semiconductor chip and the counterpart element, the semiconductor chip being provided with a first connection pad formed in a first principal surface of the chip, the counterpart element being provided with a second connection pad and a third connection pad formed in a second principal surface of the element, the base substrate being provided with a connection terminal, the method comprising the steps of:
connecting the third connection pad to the connection terminal of the base substrate by a metal wire;
forming a deformable stud bump on the second connection pad;
applying an adhesive resin to the second principal surface of the counterpart element; and
pressing the first connection pad against the stud bump formed on the second connection pad.

19. The method according to claim 18, wherein the deformable stud bump is made of gold and includes a pointed portion against which the first connection pad is pressed.
